(19) United States
(12) Patent Application Publication
(10) Pub. No.: US 2008/0237662 A1
(43) Pub. Date: Oct. 2, 2008

(54) SEMICONDUCTOR DEVICE AND METHOD OF FABRICATING THE SAME

(75) Inventors: HSIU-LIEN LIAO, TAICHUNG CITY (TW); NENG-KUO CHEN, HSINCHU CITY (TW); JEI-MING CHEN, TAIPEI COUNTY (TW); TENG-CHUN TSAI, HSINCHU (TW); CHIEN-CHUNG HUANG, TAICHUNG HSIEN (TW)

Correspondence Address: J C PATENTS, INC., 4 VENTURE, SUITE 250, IRVINE, CA, 92618, US

(73) Assignee: UNITED MICROELECTRONICS CORP., HSINCHU (TW)

(21) Appl. No.: 12/118,382

(22) Filed: May 9, 2008

Related U.S. Application Data
(62) Division of application No. 11/691,213, filed on Mar. 26, 2007.

(51) Int. Cl. H01L 29/00

(52) U.S. Cl. 257/288; 257/E29.001

(57) ABSTRACT

A method of fabricating a semiconductor device is provided. A MOS transistor is formed on a substrate, and then a contact etching stop layer (CESL) is formed over the substrate. A first UV-curing process is performed to increase the stress of the CESL. A dielectric layer is formed on the CESL, and then a second UV-curing process is performed to increase the stress of the dielectric layer. A CMP process is conducted, and then a cap layer is formed on the dielectric layer.

### CROSS-REFERENCE TO RELATED APPLICATION

This application is a divisional of an application Ser. No. 11/691,213, filed on Mar. 26, 2007, now pending. The entirety of each of the above-mentioned patent applications is hereby incorporated by reference herein and made a part of this specification.

### BACKGROUND OF THE INVENTION

1. Field of Invention

This invention relates to an integrated circuit (IC) device and fabrication of the same, and more particularly to a semiconductor device that is based on a metal-oxide-semiconductor (MOS) transistor and a method of fabricating the same.

2. Description of Related Art

With the development of the semiconductor technology, the speed of transistors is unceasingly increased. However, due to the limited mobility of electrons and holes in the silicon channels, the speed of transistor is limited.

One way to improve the device performance is to adjust the mechanical stresses of the channels and thereby raise the mobility of electrons and holes in the channels.

A prior-art method of adjusting the stress is to form a strained semiconductor material, such as silicon germanium alloy (SiGe), as the major material of source/drain (S/D) regions. The method includes removing portions of the substrate at the predetermined positions of the S/D regions to form cavities and then filling SiGe into the cavities with selective epitaxial growth (SEG). Because the effective electron mass and the effective hole mass are smaller in germanium than in silicon, the mobility of electrons and holes can be raised by forming the S/D regions mainly from SiGe. Thereby, the performance of the device can be improved.

Another prior-art method of adjusting the stress is to treat the surface of the dielectric layer covering the MOS transistor with O₂/O₃/N₂, so as to increase the stress of the dielectric layer and thereby increase the On-current (I_{On}) of the device. However, the plasma treatment causes charge accumulation that lowers the performance of the device. Moreover, since only the surface of the dielectric layer can be treated with the plasma, the moisture inside the dielectric layer cannot be removed so that a contact open problem easily occurs. In addition, the plasma treatment causes dangling Si—O or Si—N bonds in the dielectric layer, so that the increase in the tensile stress of the dielectric layer is limited.

### SUMMARY OF THE INVENTION

Accordingly, this invention provides a semiconductor device and a method of fabricating the same, which can increase the stresses of the CESL and the dielectric layer so that the Iₒₙ current of the device is increased improving the Iₒₙ gain.

Another object of this invention is to reduce the amount of moisture in the dielectric layer and thereby prevent the contact open problem.

Still another object of this invention is to prevent formation of dangling Si—O or Si—N bond in the dielectric layer and thereby increase the tensile stress of the same.

A method of fabricating a semiconductor device of this invention is applied to a substrate having a MOS transistor thereon. The method includes a step of forming a contact etching stop layer (CESL) over the substrate, a first UV-curing process, a step of forming a dielectric layer on the contact etching stop layer, a second UV-curing process, a step of forming a cap layer on the dielectric layer, and a chemical mechanical polishing (CMP) process.

In some embodiments, each of the first and the second UV-curing processes may be conducted at a temperature between 150° C. and 700° C. Each of the first and the second UV-curing processes may be conducted for a period between 30 seconds and 60 minutes. Each of the first and the second UV-curing processes may be conducted under a pressure between 3 mTorr and 500 Torr. Each of the first and second UV-curing processes may utilize UV light having a wavelength between 100 nm and 400 nm.

In an embodiment, the step of forming the CESL over the substrate, the first UV-curing process, the step of forming the dielectric layer on the contact etching stop layer, the second UV-curing process, the CMP process and the step of forming the cap layer on the dielectric layer are performed in sequence. In another embodiment, the step of forming the CESL over the substrate, the first UV-curing process, the step of forming the dielectric layer on the contact etching stop layer, the step of forming the cap layer on the dielectric layer, the second UV-curing process and the CMP process and are performed in sequence. In still another embodiment, the step of forming the CESL over the substrate, the first UV-curing process, the step of forming the dielectric layer on the contact etching stop layer, the step of forming the cap layer on the dielectric layer, the CMP process and the second UV-curing process are performed in sequence.

In some embodiments, a barrier oxide layer may be further formed over the substrate before the contact etching stop layer is formed.

Another method of fabricating a semiconductor device of the invention is applied to a substrate having a MOS transistor thereon. The method includes a step of forming a first contact etching stop layer over the substrate, a first UV-curing process, a step of forming a second contact etching stop layer on the first contact etching stop layer, a step of forming a dielectric layer on the second contact etching stop layer, a second UV-curing process, a step of forming a cap layer on the dielectric layer, and a chemical mechanical polishing (CMP) process.

In some embodiments, each of the first and the second UV-curing processes may be conducted at a temperature between 150° C. and 700° C. Each of the first and the second UV-curing processes may be conducted for a period between 30 seconds and 60 minutes. Each of the first and the second UV-curing processes may be conducted under a pressure between 3 mTorr and 500 Torr. Each of the first and second UV-curing processes may utilize UV light having a wavelength between 100 nm and 400 nm.

In an embodiment, the step of forming the first contact etching stop layer over the substrate, the first UV-curing process, the step of forming the second contact etching stop layer on the first contact etching stop layer, the step of forming the dielectric layer on the second contact etching stop layer, the second UV-curing process, the CMP process and the step of forming the cap layer on the dielectric layer are performed in sequence. In another embodiment, the step of forming the first contact etching stop layer over the substrate, the first UV-curing process, the step of forming the second contact etching stop layer on the first contact etching stop layer, the step of forming the dielectric layer on the second contact etching stop layer, the step of forming the cap layer on the dielectric layer, the second UV-curing process and the CMP process are performed in sequence. In still another embodiment, the step of forming the first contact etching stop layer over the substrate, the first UV-curing process, the step of forming the second contact etching stop layer on the first contact etching stop layer, the step of forming the dielectric layer on the second contact etching stop layer, the step of forming the cap layer on the dielectric layer, the CMP process and the second UV-curing process are performed in sequence.

In some embodiments, a barrier oxide layer may be further formed over the substrate before the first contact etching stop layer is formed.

Still another method of fabricating a semiconductor device of this invention is also applied to a substrate having a MOS transistor thereon. The method includes a step of forming a first contact etching stop layer over the substrate, a first UV-curing process, a step of forming a second contact etching stop layer on the first contact etching stop layer, a second UV-curing process, a step of forming a dielectric layer on the second contact etching stop layer, a third UV-curing process, a step of forming a cap layer on the dielectric layer, and a chemical mechanical polishing (CMP) process.

In some embodiments, each of the first to the third UV-curing processes may be conducted at a temperature between 150° C. and 700° C. Each of the first to the third UV-curing processes may be conducted for a period between 30 seconds and 60 minutes. Each of the first to the third UV-curing processes may be conducted under a pressure between 3 mTorr and 500 Torr. Each of the first to the third UV-curing processes may utilize UV light having a wavelength between 100 nm and 400 nm.

In an embodiment, the step of forming the first contact etching stop layer over the substrate, the first UV-curing process, the step of forming the second contact etching stop layer on the first contact etching stop layer, the second UV-curing process, the step of forming the dielectric layer on the second contact etching stop layer, the third UV-curing process, the CMP process and the step of forming the cap layer on the dielectric layer are performed in sequence. In another embodiment, the step of forming the first contact etching stop layer over the substrate, the first UV-curing process, the step of forming the second contact etching stop layer on the first contact etching stop layer, the second UV-curing process, the step of forming the dielectric layer on the second contact etching stop layer, the step of forming the cap layer on the dielectric layer, the third UV-curing process and the CMP process are performed in sequence. In still another embodiment, the step of forming the first contact etching stop layer over the substrate, the first UV-curing process, the step of forming the second contact etching stop layer on the first contact etching stop layer, the second UV-curing process, the step of forming the dielectric layer on the second contact etching stop layer, the step of forming the cap layer on the dielectric layer, the CMP process and the third UV-curing process are performed in sequence.

In some embodiments, a barrier oxide layer may be further formed over the substrate before the first contact etching stop layer is formed.

A semiconductor device of this invention includes a MOS transistor on a substrate, a contact etching stop layer (CESL) covering the MOS transistor, a dielectric layer disposed on the contact etching stop layer and having a stress of 0.1 GPa to 1.0 GPa, and a cap layer on the dielectric layer.

The contact etching stop layer may include silicon nitride. The semiconductor device may further include a barrier oxide layer under the contact etching stop layer, wherein the barrier oxide layer may include silicon oxide.

By utilizing this invention, the stresses of the CESL and the dielectric layer can be increased so that the I_{On} current of the device is increased improving the I_{On} gain. Meanwhile, the amount of moisture in the dielectric layer can be reduced to prevent contact open, and formation of dangling bonds in the dielectric layer can be prevented to increase the tensile stress of the dielectric layer.

In order to make the aforementioned and other objects, features and advantages of the present invention comprehensible, a preferred embodiment accompanied with figures is described in detail below.

### BRIEF DESCRIPTION OF THE DRAWINGS

FIG. 1 illustrates a cross-sectional view of a semiconductor device according to some embodiments of this invention.

FIG. 2 shows a flow chart of fabricating a semiconductor device according to a first embodiment of this invention.

FIG. 3 shows a flow chart of fabricating a semiconductor device according to a second embodiment of this invention.

FIG. 4 shows a flow chart of fabricating a semiconductor device according to a third embodiment of this invention.

FIG. 5 shows a flow chart of fabricating a semiconductor device according to a fourth embodiment of this invention.

FIG. 6 shows a flow chart of fabricating a semiconductor device according to a fifth embodiment of this invention.

FIG. 7 shows a flow chart of fabricating a semiconductor device according to a sixth embodiment of this invention.

FIG. 8 shows a flow chart of fabricating a semiconductor device according to a seventh embodiment of this invention.

FIG. 9 shows a flow chart of fabricating a semiconductor device according to an eighth embodiment of this invention.

FIG. 10 shows a flow chart of fabricating a semiconductor device according to a ninth embodiment of this invention.

### DESCRIPTION OF EMBODIMENTS

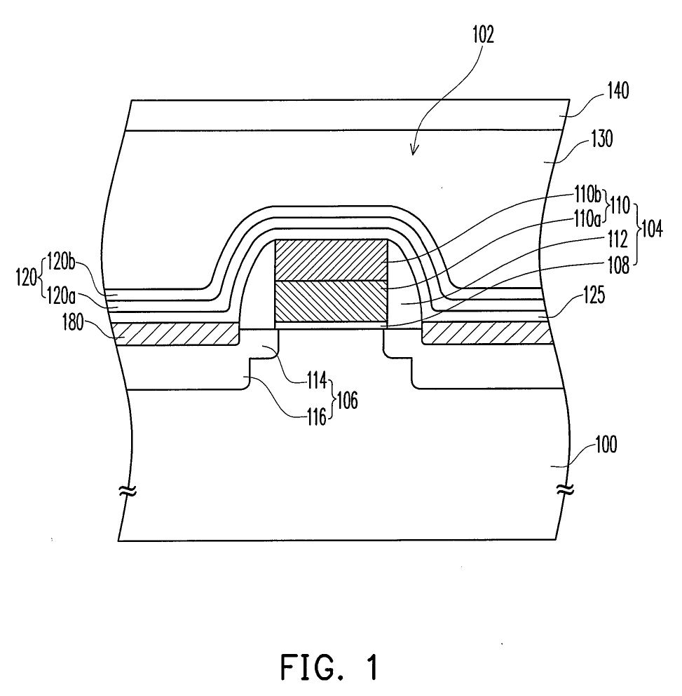

FIG. 1 illustrates a cross-sectional view of a semiconductor device according to some embodiments of this invention.

Referring to FIG. 1, the substrate 100 has thereon a MOS transistor 102, which may be a NMOS transistor or a PMOS transistor. The MOS transistor 102 includes a gate structure 104 and two source/drain (S/D) regions 106. The gate structure 104 includes a gate dielectric layer 108, a gate electrode 110 and a spacer 112. The material of the gate dielectric layer 108 may be silicon oxide, and that of the gate electrode 110 may be a Si-based material, such as, doped silicon, undoped silicon, doped poly-Si or undoped poly-Si. When the gate electrode 110 includes doped silicon or doped poly-Si, the dopant in the silicon or poly-Si may be an N-type dopant or a P-type dopant. In an embodiment, the gate electrode 110 includes a doped poly-Si layer 110a and a metal silicide layer 110b, which may include a silicide of a refractory metal material like Ni, Co, Ti, Cu, Mo, Ta, W, Er, Zr, Pt or an alloy of two among these metal elements. The spacer 112 may include silicon oxide or silicon nitride, possibly a single-layer spacer or a double-layer spacer.

Each S/D regions 106 include an S/D extension region 114 and an S/D contact region 116. Each S/D regions 106 includes an N-type dopant like phosphorous or arsenic, or a P-type dopant like boron or BF₂⁺. The S/D contact region 116 is based on a semiconductor material, and is formed by, for example, forming a cavity in the substrate 100 and then conducting a selective epitaxy growth (SEG) process to form an epitaxial layer of the semiconductor material in the cavity. The doping of the S/D contact region 116 may be done in-situ in the SEG process or through ion implantation after the SEG process. In an embodiment where the MOS transistor 102 is a NMOS transistor and the S/D contact regions 116 are N-doped, the material of the S/D contact regions may be carbon-doped silicon. In an embodiment where the MOS transistor 102 is a PMOS transistor and the S/D contact regions 116 are P-doped, the material of the S/D contact regions may be Si—Ge alloy (SiGe).

In some embodiments, the S/D contact region 116 further has a metal silicide layer 180, which may include a silicide of a refractory metal material like Ni, Co, Ti, Cu, Mo, Ta, W, Er, Zr, Pt or an alloy of two among these metal elements. Formation of the metal silicide layer 180 may include the following step. A layer of the refractory metal material is formed over the substrate with, for example, one of evaporation, sputtering, electroplating, CVD, PVD and so forth, and then annealing is conducted to react the metal material with silicon to form a metal silicide.

The MOS transistor 102 is covered by a contact etching stop layer 120, a dielectric layer 130 and a cap layer 140. The material of the contact etching stop layer 120 may be silicon nitride, which may be formed through a high-temperature nitride process, PECVD, sub-atmospheric CVD (SACVD) or LPCVD. In an embodiment, the contact etching stop layer 120 is formed to a desired thickness, such as about 100-2000 angstroms, in a single deposition step and then subjected to a UV-curing process that increases the stress thereof. For a NMOS transistor, a v-curing process to the contact etching stop layer 120 can increase the tensile stress thereof. In another embodiment, the contact etching stop layer 120 is formed to a desired thickness in two deposition steps, wherein each deposition step may form a layer of about 50-1000 angstroms in thickness and a UV-curing process can be conducted between the two deposition steps to increase the stress. In still another embodiment, the contact etching stop layer 120 is formed to a desired thickness also in two deposition steps, which form two sub-layers 120a and 120b each possibly having a thickness of about 50-1000 angstroms. A UV-curing process is conducted after each deposition step to increase the stress of the contact etching stop layer 120. In the above embodiments, each UV-curing process may be conducted at a temperature between 150° C. and 700° C. Each UV-curing process may be conducted for a period between 30 seconds and 60 minutes. Each UV-curing process may be done under a pressure of 3 mTorr to 500 Torr. Each UV-curing process may utilize UV light having a wavelength between 100 nm and 400 nm.

The material of the dielectric layer 130 may be silicon oxide, undoped silicate glass (USG), borophosphosilicate glass (BPSG), phosphosilicate glass (PSG) or a low-k material, for example. A low-k material is a dielectric material having a dielectric constant lower than 4, such as fluorosilicate glass (FSG), a silsesquioxane material like hydrogen silsesquioxane (HSG), methyl silsesquioxane (MSQ) or a hybrido-organo-siloxane polymer (HOSP), an aromatic hydrocarbon compound like SiLK, a fluoro-polymer like PFCB, CYTOP or Teflon, poly(arylether) like PAE-2 or FLARE, a porous polymer like XLK, Nanofoam or Aerogel, or Coral. The dielectric layer 130 may be formed through PECVD, SACVD, a high aspect ratio process (HARP), a high-temperature oxide (HTO) process or LPCVD. The thickness of the dielectric layer 130 may be with the range of about 500-5000 angstroms.

A UV-curing process is conducted after the dielectric layer 130 is formed, which can reduce the number of the dangling bonds like Si—OH bonds to increase the stress of the dielectric layer 130 and prevent the contact open problem. For a NMOS transistor, a UV-curing process can increase the stress of the dielectric layer 130 to 0.1-1.0 GPa, so as to increase the On-current (I_{On}) of the device. The wavelength of the UV light used in the UV-curing process may be between 100 nm and 400 nm. The temperature set in the UV-curing process may be within the range of 150-700° C. The duration of the UV-curing process may be within the range of 30-60 minutes. The pressure set in the UV-curing process may be within the range of 3 mTorr to 500 Torr.

The cap layer 140 may include silicon nitride, silicon carbide, silicon carboxide (SiCO), silicon carbonitride (SiCN), silicon carbonitroxide (SiCNO) or SiON, and may be formed with a high-temperature (oxy)nitride process, PECVD, SACVD or LPCVD.

In an embodiment, the UV-curing of the dielectric layer 130 is conducted just after the dielectric layer 130 is formed, and then a CMP process to planarize the dielectric layer 130. Thereafter, the cap layer 140 is deposited.

In another embodiment, the UV-curing of the dielectric layer 130 is conducted after the dielectric layer 130 and the cap layer 140 are formed, and then a CMP process is conducted to planarize the cap layer 140 and the dielectric layer 130.

In still another embodiment, a CMP process is conducted after the dielectric layer 130 and the cap layer 140 are formed to planarize the cap layer 140 and the dielectric layer 130 and thereby facilitate the subsequent lithography process. After that, the UV-curing of the dielectric layer 130 is conducted.

In some embodiments, not only the contact etching stop layer 120, the dielectric layer 130 and the cap layer 140 are disposed over the MOS transistor 102, but also a barrier oxide layer 125 is disposed under the contact etching stop layer 120. The barrier oxide layer 125 may include silicon oxide, and may be formed through a high-temperature oxidation (HTO) process, PECVD, SACVD or LPCVD.

Through a UV-curing process, the stress of the dielectric layer 130 can be increased to 0.1 GPa to 1.0 GPa.

Moreover, as compared with the prior art where the dielectric layer surface is treated with plasma after or before being polished with CMP, the method of this invention can prevent accumulation of charges so that the device performance can be good. Moreover, plasma can merely affect the surface of the dielectric layer, while the UV light can affect the whole dielectric layer to remove more moisture. In addition, a plasma treatment causes formation of dangling Si—O or Si—N bonds so that the tensile stress of the dielectric layer is decreased.

Accordingly, the method of fabricating a semiconductor device of this invention can be described with the following embodiments.

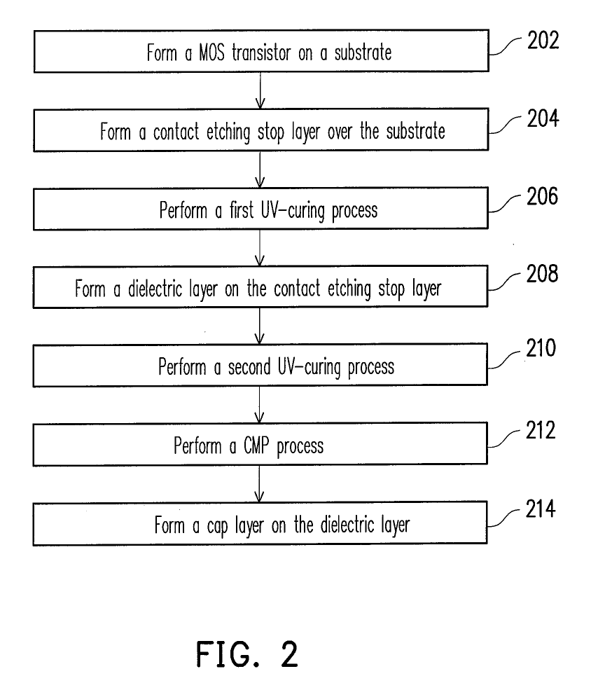

FIGS. 2-10 show flow charts of fabricating a semiconductor device respectively according to the first to the ninth embodiments of this invention.

Referring to FIG. 2, the following steps 202-214 are conducted in sequence in the first embodiment of this invention. In the step 202, a MOS transistor is formed on a substrate. In next step 204, a contact etching stop layer (CESL) is formed over the substrate. In next step 206, a first UV-curing process is conducted to increase the stress of the CESL. In next step 208, a dielectric layer is formed on the CESL. In next step 210, a second UV-curing process is conducted to increase the stress of the dielectric layer. In next step 212, a CMP process is conducted to planarize the dielectric layer. In next step 214, a cap layer is formed on the dielectric layer.

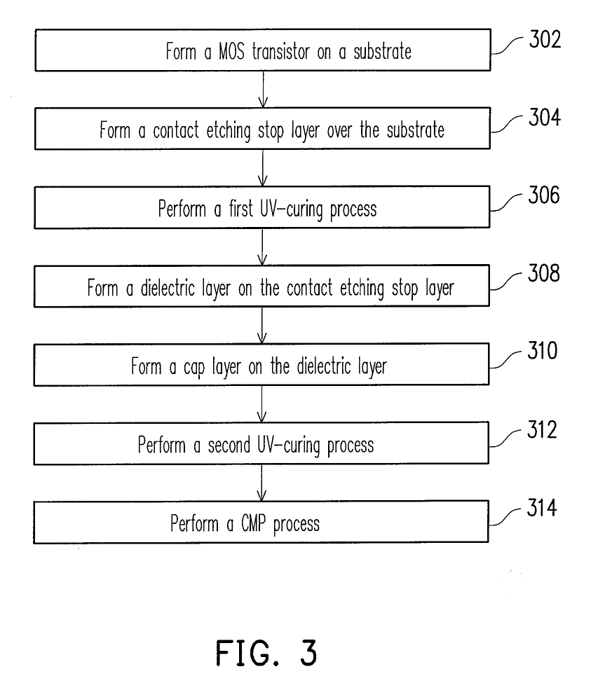

Referring to FIG. 3, the following steps 302-314 are conducted in sequence in the second embodiment of this invention. In the step 302, a MOS transistor is formed on a substrate. In next step 304, a CESL is formed over the substrate. In next step 306, a first UV-curing process is conducted to increase the stress of the CESL. In next step 308, a dielectric layer is formed on the CESL. In next step 310, a cap layer is formed on the dielectric layer. In next step 312, a second UV-curing process is conducted to increase the stress of the dielectric layer. In next step 314, a CMP process is conducted to planarize the cap layer and the dielectric layer.

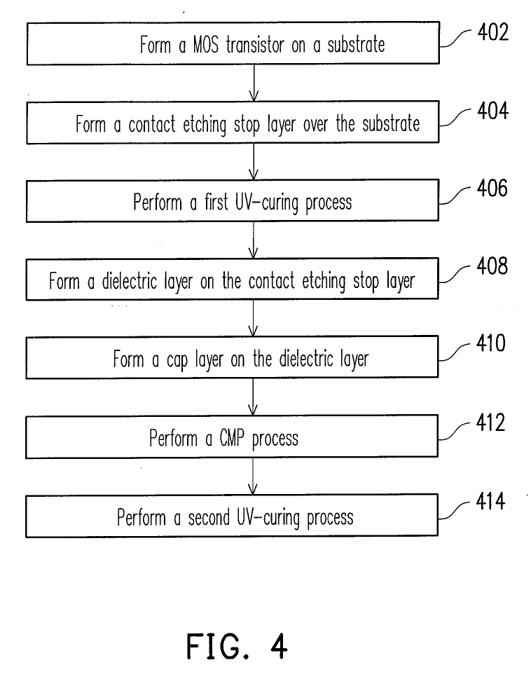

Referring to FIG. 4, the following steps 402-414 are conducted in sequence in the third embodiment of this invention. In the step 402, a MOS transistor is formed on a substrate. In next step 404, a CESL is formed over the substrate. In next step 406, a first UV-curing process is conducted to increase the stress of the CESL. In next step 408, a dielectric layer is formed on the CESL. In next step 410, a cap layer is formed on the dielectric layer. In next step 412, a CMP process is conducted to planarize the cap layer and the dielectric layer. In next step 414, a second UV-curing process is conducted to increase the stress of the dielectric layer.

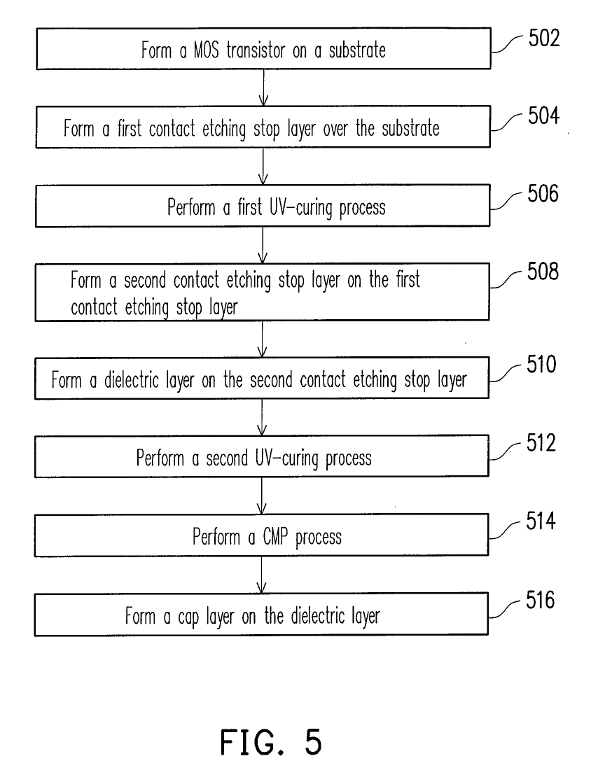

Referring to FIG. 5, the following steps 502-516 are conducted in sequence in the fourth embodiment of this invention. In the step 502, a MOS transistor is formed on a substrate. In next step 504, a first CESL is formed over the substrate. In next step 506, a first UV-curing process is conducted to increase the stress of the first CESL. In next step 508, a second CESL is formed on the first CESL. In next step 510, a dielectric layer is formed on the second CESL. In next step 512, a second UV-curing process is conducted to increase respective stresses of the dielectric layer and the second CESL. In next step 514, a CMP process is conducted to planarize the dielectric layer. In next step 516, a cap layer is formed on the dielectric layer.

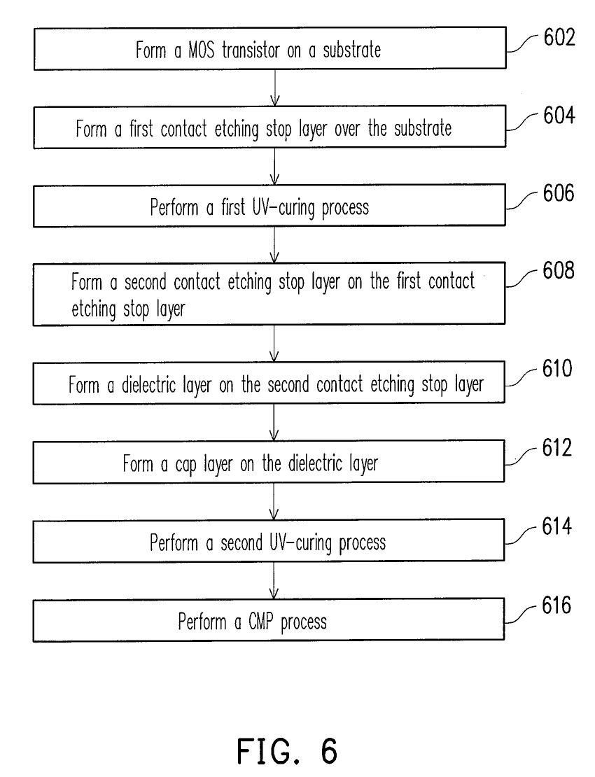

Referring to FIG. 6, the following steps 602-616 are conducted in sequence in the fifth embodiment of this invention. In the step 602, a MOS transistor is formed on a substrate. In next step 604, a first CESL is formed over the substrate. In next step 606, a first UV-curing process is conducted to increase the stress of the first CESL. In next step 608, a second CESL is formed on the first CESL. In next step 610, a dielectric layer is formed on the second CESL. In next step 612, a cap layer is formed on the dielectric layer. In next step 614, a second UV-curing process is conducted to increase respective stresses of the dielectric layer and the second CESL. In next step 616, a CMP process is conducted to planarize the cap layer and the dielectric layer.

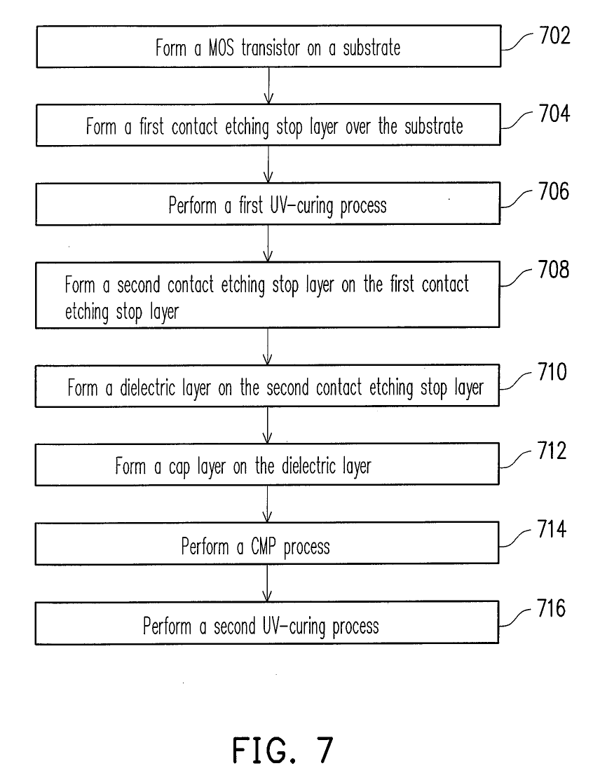

Referring to FIG. 7, the following steps 702-716 are conducted in sequence in the sixth embodiment of this invention. In the step 702, a MOS transistor is formed on a substrate. In next step 704, a first CESL is formed over the substrate. In next step 706, a first UV-curing process is conducted to increase the stress of the first CESL. In next step 708, a second CESL is formed on the first CESL. In next step 710, a dielectric layer is formed on the second CESL. In next step 712, a cap layer is formed on the dielectric layer. In next step 714, a CMP process is conducted to planarize the cap layer and the dielectric layer. In next step 716, a second UV-curing process is conducted to increase respective stresses of the dielectric layer and the second CESL.

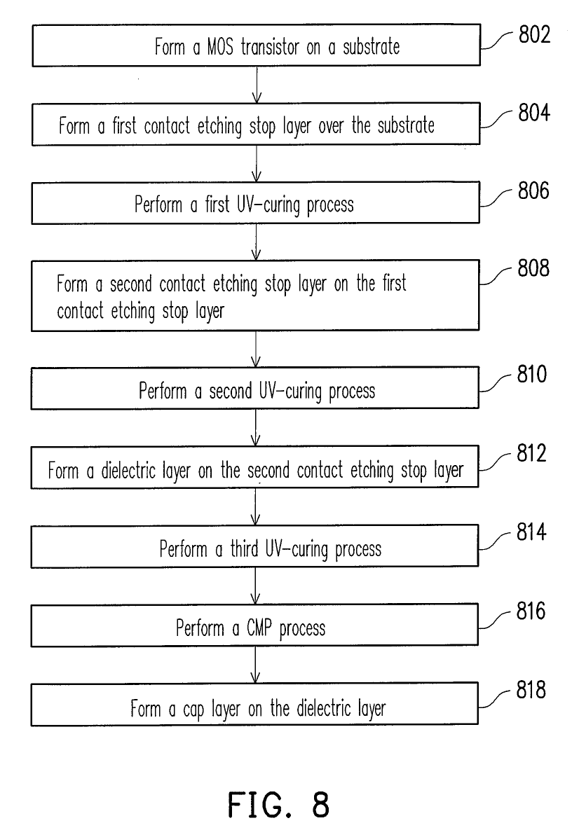

Referring to FIG. 8, the following steps 802-818 are conducted in sequence in the seventh embodiment of this invention. In the step 802, a MOS transistor is formed on a substrate. In next step 804, a first CESL is formed over the substrate. In next step 806, a first UV-curing process is conducted to increase the stress of the first CESL. In next step 808, a second CESL is formed on the first CESL. In next step 810, a second UV-curing process is conducted to increase the stress of the second CESL. In next step 812, a dielectric layer is formed on the second CESL. In next step 814, a third UV-curing process is conducted to increase the stress of the dielectric layer. In next step 816, a CMP process is conducted to planarize the dielectric layer. In next step 818, a cap layer is formed on the dielectric layer.

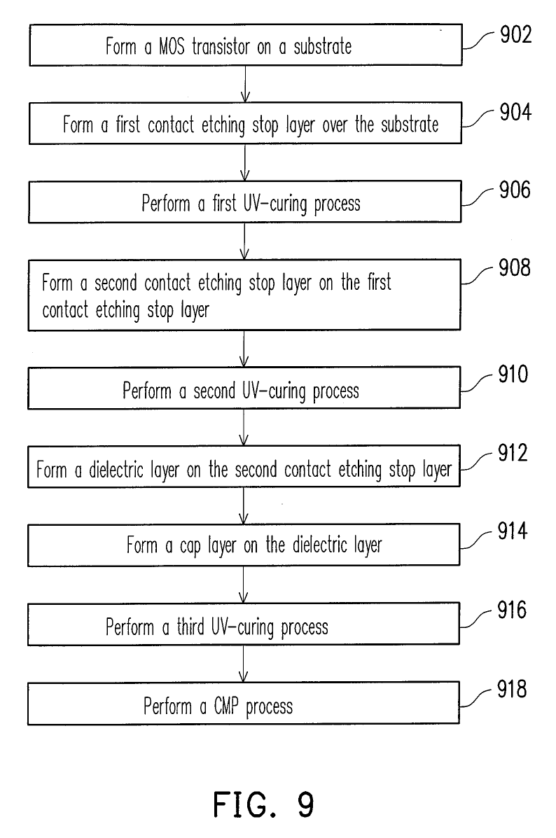

Referring to FIG. 9, the following steps 902-918 are conducted in sequence in the eighth embodiment of this invention. In the step 902, a MOS transistor is formed on a substrate. In next step 904, a first CESL is formed over the substrate. In next step 906, a first UV-curing process is conducted to increase the stress of the first CESL. In next step 908, a second CESL is formed on the first CESL. In next step 910, a second UV-curing process is conducted to increase the stress of the second CESL. In next step 912, a dielectric layer is formed on the second CESL. In next step 914, a cap layer is formed on the dielectric layer. In next step 916, a third UV-curing process is conducted to increase the stress of the dielectric layer. In next step 918, a CMP process is conducted to planarize the cap layer and the dielectric layer.

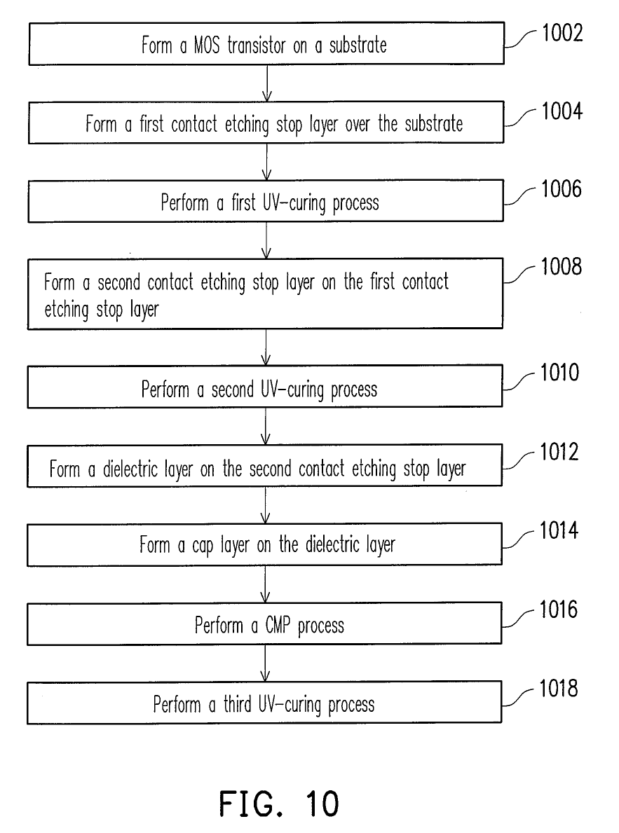

Referring to FIG. 10, the following steps 1002-1018 are conducted in sequence in the ninth embodiment of this invention. In the step 1002, a MOS transistor is formed on a substrate. In next step 1004, a first CESL is formed over the substrate. In next step 1006, a first UV-curing process is conducted to increase the stress of the first CESL. In next step 1008, a second CESL is formed on the first CESL. In next step 1010, a second UV-curing process is conducted to increase the stress of the second CESL. In next step 1012, a dielectric layer is formed on the second CESL. In next step 1014, a cap layer is formed on the dielectric layer. In next step 1016, a CMP process is conducted to planarize the cap layer and the dielectric layer. In next step 1018, a third UV-curing process is conducted to increase the stress of the dielectric layer.

### EXAMPLES

### Example 1

A silicon nitride layer of 550 nm thick as a CESL is deposited over a substrate with a high-temperature nitride process, a undoped silicate glass (USG) layer of 2000 nm thick is deposited with CVD, and then a UV-curing process is conducted for 20 minutes. In the UV-curing process, the wavelength of the UV light used is 100-400 nm, the temperature is 400° C. and the pressure is 200 Torr.

### Example 2

A silicon nitride layer of 550 nm thick as a CESL is deposited over a substrate with a high-temperature nitride process, and then a UV-curing process is conducted for 5 minutes. An undoped silicate glass (USG) layer of 2000 nm thick is deposited with CVD, and then another UV-curing process is conducted for 20 minutes. In the UV-curing process, the wavelength of the UV light used is 100-400=nm, the temperature is 400° C. and the pressure is 200 Torr.

### Comparative Example 1

A silicon nitride layer of 550 nm thick as a CESL is deposited over a substrate with a high-temperature nitride process, a UV-curing process is conducted for 5 minutes, and then a undoped silicate glass (USG) layer of 2000 nm thick is deposited with CVD. In the UV-curing process, the wavelength of the UV light used is 100-400 nm, the temperature is 400° C. and the pressure is 200 Torr.

### Comparative Example 2

A silicon nitride layer of 550 nm thick as a CESL is deposited over a substrate with a high-temperature nitride process, and then a undoped silicate glass (USG) layer of 2000 nm thick is deposited with CVD.

The results of the above experiments are listed in Table 1.

TABLE 1

| | Step | Example 1 | Example 2 | *C. Example 1 | *C. Example 2 |
|---|---|---|---|---|---|
| 1 | SiN deposition | 550 nm | 550 nm | 550 nm | 550 nm |
| 2 | 1^{st} UV-curing | none | 5 minutes | 5 minutes | none |
| 3 | USG deposition | 2000 nm | 2000 nm | 2000 nm | 2000 nm |
| 4 | 2^{nd} UV-curing | 20 minutes | 20 minutes | none | none |
| 5 | Stress (Mpa) | 600 | 900 | 530 | 200 |

*C. Example: Comparative Example

As indicated by the experiment results, by treating a USG layer with UV-curing for 20 minutes, the stress of the USG layer can be increased by about 50%.

As mentioned above, by utilizing this invention, the stresses of the CESL and the dielectric layer can be increased so that the I_{On} current of the device is increased improving the I_{On} gain. Meanwhile, the amount of moisture in the dielectric layer can be reduced to prevent contact open, and formation of dangling bonds in the dielectric layer can be prevented to increase the tensile stress of the dielectric layer.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A semiconductor device, comprising:
a MOS transistor on a substrate;
a contact etching stop layer (CESL) covering the MOS transistor;
a dielectric layer on the contact etching stop layer, having a stress of 0.1 GPa to 1.0 GPa; and
a cap layer on the dielectric layer.

2. The semiconductor device of claim 1, wherein the contact etching stop layer comprises silicon nitride.

3. The semiconductor device of claim 1, further comprising a barrier oxide layer under the contact etching stop layer.

4. The semiconductor device of claim 3, wherein the barrier oxide layer comprises silicon oxide.
